(19) United States
(12) Patent Application Publication
(10) Pub. No.: US 2025/0243324 A1
(43) Pub. Date: Jul. 31, 2025

(54) POLYIMIDE PRECURSOR COMPOSITION AND METHOD FOR PRODUCING THE SAME

(71) Applicant: UBE Corporation, Ube-Shi (JP)

(72) Inventors: Norio MIURA, Ube-shi (JP); Sousuke HONMA, Ube-shi (JP); Shohei INOUE, Ube-shi (JP); Nobuharu HISANO, Ube-shi (JP); Nobu IIZUMI, Ube-shi (JP); Takaaki MANAKA, Tokyo (JP); Dai TAGUCHI, Tokyo (JP)

(21) Appl. No.: 18/702,162

(22) PCT Filed: Nov. 2, 2022
(86) PCT No.: PCT/JP2022/040991

§ 371 Date: Apr. 17, 2024

(30) Foreign Application Priority Data
Nov. 2, 2021 (JP) 2021-179854

(51) Int. Cl. C08G 73/10

(52) U.S. Cl. CPC C08G 73/1067; C08G 73/1025

(57) ABSTRACT

A polyimide precursor for producing a flexible electronic device substrate that provides a polyimide with reduced charge-up, particularly a polyimide in the form of a film. When a polyimide film having a thickness of 10 μm is formed using the polyimide precursor, and a pair of electrodes is formed with a distance d on the polyimide film, and when the polyimide film is irradiated with a laser beam while applying a DC voltage with an electric field strength of 0.1 to 10 V/μm between the pair of electrodes; two SHG lights are observed between the pair of electrodes and satisfy a symmetry ratio of 0.5 or more. The symmetry ratio (LR ratio)=Iₛₘₐₗₗ/I_{large}, wherein, I_{large} represents the peak intensity of the SHG light with the larger intensity, and Iₛₘₐₗₗ represents the peak intensity of the SHG light with the smaller intensity.

### TECHNICAL FIELD

The present invention relates to a polyimide precursor composition suitable for use in electronic device applications such as flexible electronic device substrates, and further relates to polyimide films for flexible electronic device substrates, laminates containing polyimide films, flexible electronic device substrates, and flexible electronic devices.

### BACKGROUND ART

As a substrate for displays such as liquid crystal displays and organic EL displays, glass has traditionally been used. However, the use of glass has problems that when it is thinned to reduce weight, it is easily broken due to lack of strength. Therefore, as a substitute for glass substrates, plastic substrates, which are lightweight and have excellent flexibility, have been proposed. In displays such as liquid crystal displays and organic EL displays, semiconductor elements such as TFTs are formed on a substrate to drive each pixel. Therefore, the substrate is required to have heat resistance and dimensional stability. Since polyimide films have excellent heat resistance, chemical resistance, mechanical strength, electrical properties, dimensional stability, and the like, they are expected to be used as a substrate for displays.

For example, Patent Document 1 discloses a method of manufacturing a flexible device, which includes forming elements and circuits necessary for a device on a polyimide film/glass substrate laminate obtained by forming a polyimide film on a glass substrate, and thereafter irradiating laser from the glass substrate side to peel off the glass substrate.

On the other hand, Non-Patent Document 1 reports a problem in which an afterimage phenomenon is observed in a flexible display using a polyimide film as a substrate. The cause of this is presumed to be charge-up on polyimide.

### CITATION LIST

### Patent Document

Patent Document 1: WO 2018/221607

### Non-Patent Document

Non-patent document 1: S. Hong et al., “Alleviation of Recoverable Residual Image Phenomenon of Flexible Organic Light-emitting Diode display”, SID Digest p 105-108 (2019)

### SUMMARY OF INVENTION

### Technical Problem

In order to solve the afterimage phenomenon as described in Non-Patent Document 1, it is considered necessary to reduce charge-up near the polyimide surface, but no solution has been known. Therefore, it is necessary to properly evaluate charge-up near the polyimide surface and provide a polyimide film that is suitable for a substrate for flexible electronic devices, particularly organic EL displays and liquid crystal displays.

An object of the present invention is to provide a polyimide precursor for producing a flexible electronic device substrate that provides a polyimide with reduced charge-up, particularly a polyimide in a form of a film, and a polyimide film for a flexible electronic device. An object of the present invention is also to provide a laminated substrate containing the polyimide film, and an electronic device such as a flexible display containing the same.

### Solution to Problem

The present invention relates to the following items.
1. A polyimide precursor for manufacturing flexible electronic device substrates,
   when a polyimide film having a thickness of 10 μm is formed using the polyimide precursor, and a pair of electrodes is formed with a distance d on the polyimide film, and when the polyimide film is irradiated with a laser beam while applying a DC voltage with an electric field strength of 0.1 to 10 V/μm between the pair of electrodes;
   two SHG lights are observed between the pair of electrodes and satisfy a symmetry ratio of 0.5 or more,
   wherein the symmetry ratio is a value expressed by the following equation.

$$Symmetry ratio ( LR ratio ) = {I}_{small} / {I}_{large}$$

(wherein, I_{large} represents a peak intensity of the SHG light with larger intensity, and Iₛₘₐₗₗ represents a peak intensity of the SHG light with smaller intensity.)
2. The polyimide precursor according to the above item 1, wherein the polyimide precursor has a weight average molecular weight of 80,000 to 300,000.
3. The polyimide precursor according to the above item 2, wherein the polyimide precursor comprises at least polyamic acid.
4. The polyimide precursor according to any one of the above items 1 to 3, wherein all tetracarboxylic acid components and all diamine components constituting the polyimide precursor satisfies an equation:

$$1. \leq X / Y \leq 1. 05$$

(wherein X represents number of moles of the tetracarboxylic acid component, and Y represents number of moles of the diamine component.)
5. The polyimide precursor according to any one of the above items 1 to 3, wherein the polyimide precursor is composed of a tetracarboxylic acid component, a diamine component, and a carboxylic acid monoanhydride, and satisfies following equations (1) and (2):

$$0.97 \leq X / Y < 1. \qquad Equation ( 1 )$$

$$1. \leq ( X + Z / 2 ) / Y \leq 1.05 \qquad Equation ( 2 )$$

(In the equation, X represents number of moles of the tetracarboxylic acid component, Y represents number of moles of the diamine component, and Z represents number of moles of the carboxylic acid monoanhydride.).
6. The polyimide precursor according to the above items 4 or 5, wherein the proportion of 3,3′,4,4′-biphenyltetracarboxylic dianhydride in all tetracarboxylic acid components is 60 mol % or more, and the amount of p-phenylenediamine in all diamine components is 60 mol % or more.
7. A polyimide film for a flexible electronic device substrate obtained from the polyimide precursor according to any one of the above items 1 to 6.
8. A laminate comprising the polyimide film according to the above item 7 and a glass substrate.
9. A flexible electronic device substrate comprising the polyimide film according to the above item 7 or the laminate according to the above item 8.
10. A flexible electronic device comprising the flexible electronic device substrate according to the above item 9 and a TFT element.
11. A method for manufacturing a flexible electronic device according to the above item 9 or 10, comprising:
applying a solution composition comprising a polyimide precursor onto a carrier substrate and imidizing thereof to form a laminate having the carrier substrate and a polyimide film.

Furthermore, the present application also discloses a method for evaluating the charge-up characteristics of polyimides.

### Advantageous Effects of Invention

According to the present invention, provided is a polyimide precursor for producing a flexible electronic device substrate that provides a polyimide, particularly a polyimide in a form of a film, with reduced charge-up, specifically a polyimide exhibiting a symmetry ratio (LR ratio) of 0.5 or more in the SHG measurement described below. Further, according to a different aspect of the present invention, provided is a polyimide film for a flexible electronic device, which has reduced charge-up exhibiting an LR ratio of 0.5 or more in SHG measurement. Furthermore, according to a different aspect of the present invention, provided is a laminated substrate including the polyimide film having the above characteristics, and a flexible electronic device such as a flexible display, particularly an organic EL display.

When the polyimide film of the present invention is used as a substrate for, for example, an organic EL display, a liquid crystal display, and the like, afterimages due to charge-up are reduced, so that a flexible display having excellent image display performance can be provided.

### BRIEF DESCRIPTION OF DRAWING

FIG. 1 is a diagram illustrating an SHG light measurement system.

FIG. 2 (a) is a diagram schematically explaining dipoles when a polyimide film is an ideal insulator. (b) A diagram schematically showing SHG light intensity.

FIG. 3 is a diagram (image) obtained by observing SHG light on a polyimide film with small charge-up.

FIG. 4 (a) is a diagram schematically illustrating the behavior of dipoles in a polyimide film in which charge-up occurs when a voltage is applied to. (b) A diagram schematically showing SHG light intensity.

FIG. 5 is a diagram (image) obtained by observing SHG light on a polyimide film with a large charge-up.

### DESCRIPTION OF EMBODIMENTS

### <<Evaluation Method of Polyimide Film Based on SHG Symmetry Ratio (LR Ratio)>>

First, a method for evaluating polyimide films and polyimide precursor compositions will be explained. This evaluation method comprises:
providing a polyimide film with a first electrode and a second electrode that are formed on the film and spaced each other at a predetermined distance;
irradiating laser light while applying a predetermined voltage between the first electrode and the second electrode;
measuring the light intensity of SHG light generated near the first electrode and SHG light generated near the second electrode;
comparing the light intensity of the SHG light generated near the first electrode and the light intensity of the SHG light generated near the second electrode to obtain a symmetry ratio (LR ratio), which will be described later; and
evaluating the polyimide or polyimide precursor based on the symmetry ratio (LR ratio).

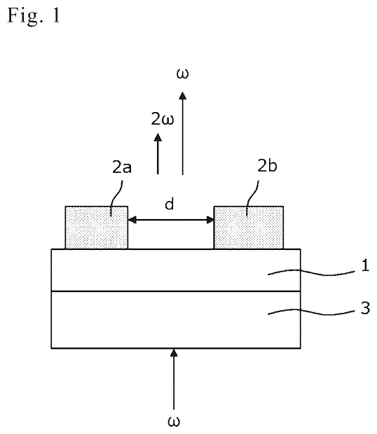

To explain the details with reference to the drawings, FIG. 1 is a diagram showing an example of a measurement system used in the present invention. A polyimide film 1 is formed on a substrate 3 that is transparent to irradiated laser light, and a first electrode 2a and a second electrode 2b are provided on the surface of the film at a predetermined distance d. As an example, the substrate 3 is a glass substrate, the thickness of the polyimide film is 10 μm, the distance d is 50 μm, the wavelength λ (frequency ω) of the irradiated laser light is 920 nm, and the voltage between the electrodes is 50V. In addition, the intensity measurement of the SHG light is performed within a range of 4 μm from the electrode end.

SHG (Second Harmonic Generation) is known as a phenomenon in which, based on a second-order nonlinear optical effect, light (second harmonic; frequency 2ω) having a frequency twice of the light (fundamental wave; frequency ω) entering the medium is generated. SHG is not observed even when the polyimide film is irradiated with laser light, but when a voltage is applied between electrodes 2a and electrode 2b, polarization occurs in the polyimide molecules, and SHG emission occurs near the electrodes between electrode 2a and electrode 2b.

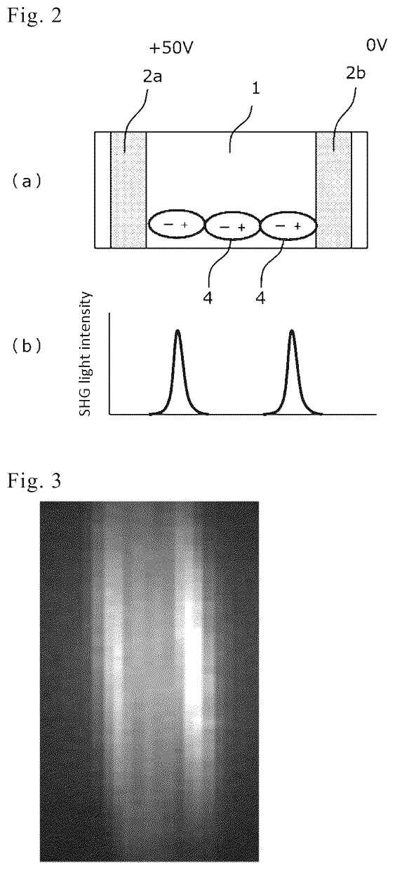

FIG. 2 (a) is a plan view of the measurement system of FIG. 1, and schematically shows the polarization of polyimide molecules. In the case of an ideal insulator in which charge-up does not occur, polarization namely dipoles 4 is generated in response to the voltage applied between the electrodes 2a and 2b, but as shown in FIG. 2 (a), at the center part, adjacent dipoles 4 cancel each other. On the other hand, since polarization remains in the vicinity of the electrodes 2a and 2b (residual dipole), when laser light (fundamental light) is irradiated, two SHG lights with peaks of light intensity in the vicinity of the electrodes 2a and 2b are observed, as schematically shown in FIG. 2 (b). FIG. 3 is an image obtained by observing actual SHG light.

Here, the symmetry ratio (LR ratio: left-right ratio) of the intensities of the two SHG lights is defined as follows.

$$Symmetry ratio ( LR ratio ) = {I}_{small} / {I}_{large}$$

(wherein, I_{large} represents the peak intensity of the SHG light with larger intensity, and Iₛₘₐₗₗ represents the peak intensity of the SHG light with smaller intensity.)

In the case of an ideal insulator, the polarization strengths near both electrodes are the same, and thus the SHG lights generated near the two electrodes have the same intensity, and the symmetry ratio (LR ratio) is 1.

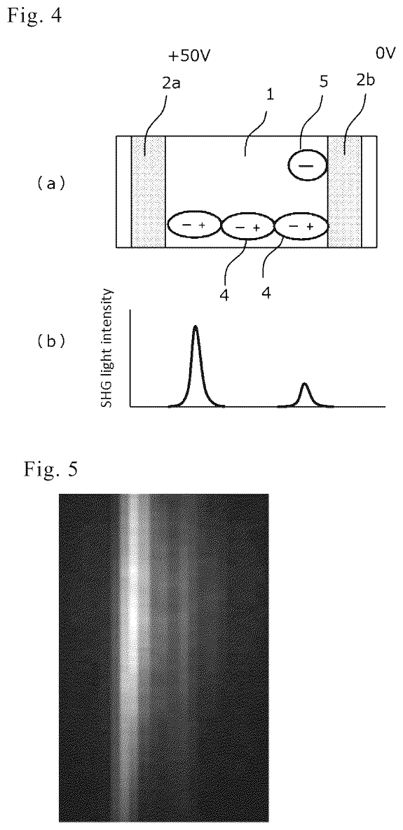

Next, in the case that charge-up occurs in the polyimide film, as shown in the schematic diagram of FIG. 4 (a), when 50 V is applied to the electrode 2a and 0 V is applied to the electrode 2b, electrons (charge 5) are injected from the electrode 2b into the polyimide film. Since the injected electrons cancel the electric field of the residual dipole described above, the SHG light intensity near electrode 2b decreases, causing the difference of SHG intensities near electrode 2a and electrode 2b as shown in FIG. 4 (b). Therefore, the symmetry ratio (LR ratio) becomes less than 1. FIG. 5 is an image obtained by observing actual SHG light. In this case, if more electrons are injected (in other words, the amount of the charge-up is larger), more dipoles are canceled out, and the electric field becomes weaker. As a result, the difference in intensity between the SHG lights generated near the left and right electrodes becomes larger. In other words, the more significant the charge-up is, the smaller the symmetry ratio (LR ratio) becomes, and the closer it becomes to zero.

In this evaluation method, the substrate 3 only needs to be one that transmits laser light (fundamental light), but generally a glass substrate such as alkali-free glass, borosilicate glass, quartz glass, and the like can be used. The thickness of the polyimide film 1 is not particularly limited, but if it is too thick, the polyimide to be measured may absorb the fundamental light of the laser (frequency ω) and/or the SHG light (frequency 2ω), and may affect the measurement, and the thicker film does not improve the measurement accuracy, therefore the thickness is usually 50 μm or less, preferably 30 μm or less, and more preferably 20 μm or less. The lower limit of the thickness is also not particularly limited, but is usually 0.5 μm or more, preferably 1 μm or more. If the distance d is too large, the electric field strength will be weakened, and thus, it is usually 100 μm or less, preferably 80 μm or less. Considering the ease of forming the electrodes, it is usually 10 μm or more, preferably 20 μm or more.

The voltage between the electrodes can be determined in relation to the distance d, but it is usually 300V or less, preferably 200V or less, and more preferably 100V or less. The relationship between the distance d and the voltage between the electrodes is preferably determined so that the electric field strength is 0.1 to 10 V/μm, preferably 0.5 to 1.0 V/μm. In addition, rather than applying direct current continuously, the voltage is generally applied in the form of a rectangular wave between 0V and a predetermined voltage with a duty ratio (ratio of voltage application time in one cycle) of 0.1 to 0.9, for example. The frequency is preferably about 1 mHz to 100 GHz.

The laser light to be irradiated is preferably selected such that the fundamental light (wavelength λ; frequency ω) and SHG light (wavelength λ/2; frequency 2ω) are in a range of high transmittance in the absorption spectrum of the polyimide film. Generally, it is preferable to use a laser beam with a wavelength in the range of 800 nm to 1500 nm. Further, while the laser devices may be operated with a continuous light oscillation, usually pulse laser oscillation having a large peak power is preferable.

The SHG light may be measured within 10 μm, preferably within 5 μm, for example within 4 μm from the electrode edge.

In addition, as an evaluation standard for polyimide films, a symmetry ratio (LR ratio) that serves as an acceptance standard can be determined depending on the purpose, but for the purpose of the present invention and the measurement conditions described later, if the LR ratio is 0.5 or more, the polyimide film is regarded as an excellent polyimide film with little charge-up. The LR ratio is preferably 0.6 or more, more preferably 0.7 or more.

Development of polyimide focusing on such charge-up properties has not been reported, nor has it actually been carried out. Naturally, existing polyimides do not satisfy the symmetry ratio (LR ratio) in SHG measurement related to the charge-up characteristics described above. Further, since the charge-up characteristics are considered to affect the state near the surface of polyimide, any chemical structure of the polyimide may be used as long as the predetermined charge-up characteristics are satisfied.

### <<Polyimide, Polyimide Precursor>>

The chemical structure of the polyimide or its precursor (polyimide precursor) of the present invention is not particularly limited as long as it satisfies the above-mentioned symmetry ratio (LR ratio), and can be selected as appropriate depending on the function to be imparted. The polyimide precursor includes a polymer having a repeating unit represented by the following general formula I:

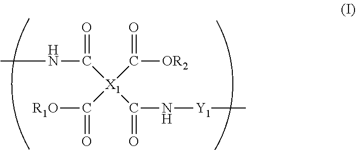

(wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms.).

Particularly preferred is a polyamic acid in which R₁ and R₂ are hydrogen atoms. In addition, polymers that have been partially imidized, that is, polymers containing repeating units in which at least one of the two amide structures in formula I is imidized, are also used as “polyimide precursors” and “polyamic acids” (in the case that remaining R₁ and R₂ are hydrogen atoms). However, the imidization ratio is preferably 50% or less, more preferably 30% or less, and still more preferably 10% or less.

The polyimide includes a repeating unit represented by the following general formula II:

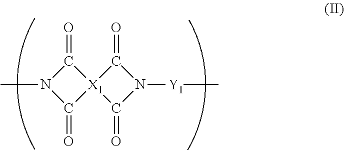

(wherein, X₁ is a tetravalent aliphatic group or aromatic group, Y₁ is a divalent aliphatic group or aromatic group.)

The chemical structure of such polyimides will be explained below by describing the structure of X₁ and Y₂ in the repeating unit (general formula (I)) and the monomers (tetracarboxylic acid component, diamine component, other components) used in the production, followed by a description of the manufacturing method.

In the present invention, the term “polyimide precursor” refers not only to a polymer (including oligomers, dimers, and the like) containing a plurality of repeating units represented by the general formula I, but also the term is used to those that include monomer compounds and the like, as long as the compound constitute at least a part of the molecular structures of “polyimide” after imidization. Therefore, in the present application, the “polyimide precursor” may be a mixture containing monomer compounds.

In the present invention, the tetracarboxylic acid component refers to a tetracarboxylic acid derivative that constitutes the molecular structure of “polyimide” after imidization, and includes tetracarboxylic acid, tetracarboxylic dianhydride, and, in addition, other tetracarboxylic acids such as tetracarboxylic acid silyl esters, tetracarboxylic acid esters, tetracarboxylic acid chlorides. In the present invention, the expression “tetracarboxylic acid component constituting the polyimide precursor” includes not only the tetracarboxylic acid derivative incorporated into the polyamic acid molecule, but also the tetracarboxylic acid derivative present as a monomer compound. Although not particularly limited, it is convenient to use tetracarboxylic dianhydride as a main component of a tetracarboxylic acid component in a production process, and thus, the explanation will be made below to such examples. On the other hand, the diamine component is a diamine compound having two amino groups (—NH₂), which is used as a starting material for producing polyimide. The expression “diamine component constituting the polyimide precursor” is used to include not only the diamine compound incorporated into the polyamic acid molecule, but also the diamine compound present as a monomer compound.

Furthermore, in this specification, the polyimide film refers to both a film formed on a substrate in a laminated state and a film that does not have a substrate supporting the film (including a self-supporting film). When the polyimide of the present invention is used as a substrate, it is preferably in the form of a film. Furthermore, the polyimide of the present invention may be in the form of a layer that is discretely or separately present on a support substrate or on a layer formed of a different material.

In one aspect of the present invention, the weight average molecular weight (Mw) of the polyimide precursor is preferably 80,000 or more, more preferably 82,000 or more, most preferably 85,000 or more, and preferably 300,000 or less, more preferably 280,000 or less, most preferably 260,000 or less. Weight average molecular weight is determined using a GPC apparatus based on a calibration curve determined from standard polystyrenes. When a polyimide film is formed from a polyimide precursor having a weight average molecular weight within the above range, a polyimide film having excellent charge-up characteristics (that is, less charge-up) can be obtained. If the weight average molecular weight is too large, the viscosity may increase and it may not be suitable for forming a film with a desired thickness. Therefore, the weight average molecular weight is preferably within the above range. The method for adjusting the weight average molecular weight of the polyimide precursor will be described in detail in the <Manufacture of polyimide precursor> section.

### <<Structure in Repeating Unit and Monomer>>

### <X₁ and Tetracarboxylic Acid Component]

When X₁ is a tetravalent group having an aromatic ring, it is preferably a tetravalent group having an aromatic ring having 6 to 40 carbon atoms.

Examples of the tetravalent group having an aromatic ring include the following groups.

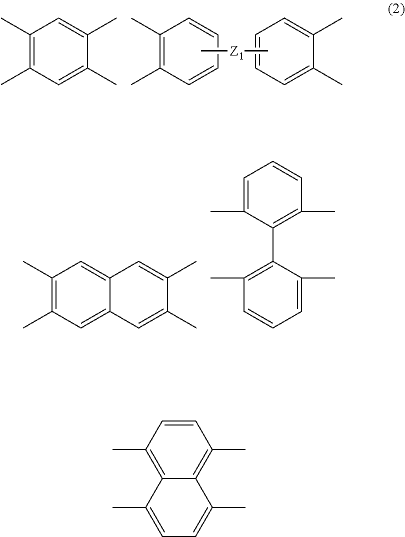

(wherein Z₁ is a direct bond, or any one of the following divalent groups:

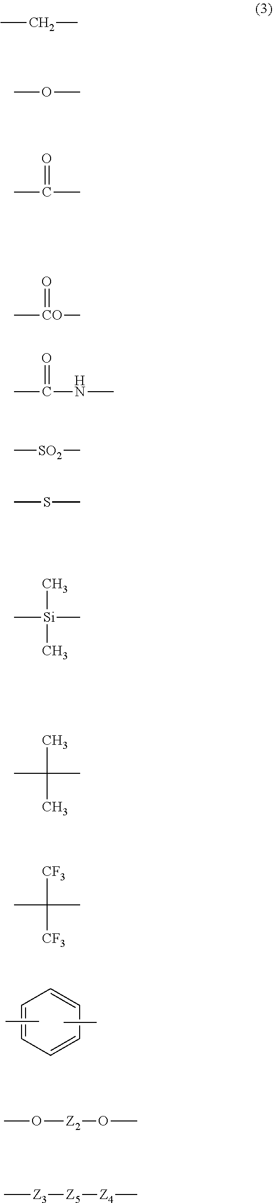

wherein Z₂ in the formula is a divalent organic group, Z₃ and Z₄ are each independently an amide bond, an ester bond and a carbonyl bond, and Z₅ is an organic group containing an aromatic ring.)

Specific examples of Z₂ include an aliphatic hydrocarbon group having 2 to 24 carbon atoms, and an aromatic hydrocarbon group having 6 to 24 carbon atoms.

Specific examples of Z₅ includes an aromatic hydrocarbon group having 6 to 24 carbon atoms.

Because the obtained polyimide material may have both high heat resistance and high transparency, the following group is particularly preferred as the tetravalent group having an aromatic ring.

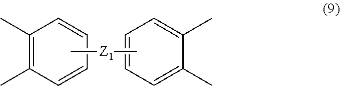

(wherein Z₁ is a direct bond, or a hexafluoroisopropylidene bond.)

Because the obtained polyimide material may have high heat resistance, high light transmittance, and low coefficient of linear thermal expansion, Z₁ is more preferably a direct bond.

In addition, preferred groups include a group in which Z₁ in the above formula (9) is a fluorenyl-containing group represented by the following formula (3A):

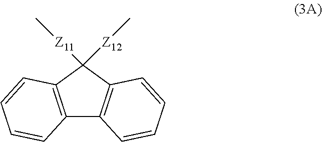

Z₁₁ and Z₁₂ are each independently, preferably the same, a single bond or a divalent organic group. Zn and Z₁₂ are preferably an organic group containing an aromatic ring, such as the formula (3A1):

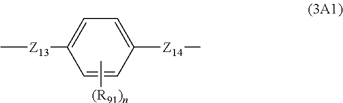

(Z₁₃ and Z₁₄ are each independently a single bond, —COO—, —OCO— or —O—, wherein when Z₁₄ is attached to a fluorenyl group, preferred is a structure in which Z₁₃ is —COO—, —OCO— or —O— and Z₁₄ is a single bond; R₉₁ is an alkyl group having 1 to 4 carbon atoms or a phenyl group, preferably methyl, and n is an integer of 0 to 4, and preferably 1.).

Examples of the tetracarboxylic acid component to provide a repeating unit of the chemical formula (II) in which X₁ is a tetravalent group having an aromatic ring, exemplified by “tetracarboxylic acid” (hereinafter, exemplified in the form of “tetracarboxylic acid”, but sometimes in the form of “tetracarboxylic acid dianhydride”), include 2,2-bis(3,4-dicarboxyphenyl) hexafluoropropane, 4-(2,5-dioxotetrahydrofuran-3-yl)-1,2,3,4-tetrahydronaphthalene-1,2-dicarboxylic acid, pyromellitic acid, 3,3′,4,4′-benzophenone tetracarboxylic acid, 3,3′,4,4′-biphenyl tetracarboxylic acid, 2,3,3′,4′-biphenyl tetracarboxylic acid. 4,4′-oxydiphthalic acid, bis(3,4-dicarboxyphenyl) sulfone, m-terphenyl-3,4,3′,4′-tetracarboxylic acid, p-terphenyl-3,4,3′,4′-tetracarboxylic acid, biscarboxyphenyl dimethylsilane, bisdicarboxyphenoxydiphenyl sulfide, and sulfonyl diphthalic acid. Preference is given to dianhydrides of these as a main component of monomers. Examples of the tetracarboxylic acid component to provide a repeating unit of the general formula (II) in which X₁ is a tetravalent group having a fluorine atom-containing aromatic ring include 2,2-bis(3,4-dicarboxyphenyl) hexafluoropropane dianhydride. Furthermore, examples of preferred compound include (9H-fluorene-9,9-diyl)bis(2-methyl-4,1-phenylene)bis(1,3-dioxo-1,3-dihydroisobenzofuran-5-carboxylate). The tetracarboxylic acid component may be used alone or in combination of a plurality of types.

When “other X₁” is a tetravalent group having an alicyclic structure, a tetravalent group having an alicyclic structure which has 4 to 40 carbon atoms is preferred, and it is more preferred that the group has at least one aliphatic 4- to 12-membered ring, more preferably an aliphatic 4-membered ring or an aliphatic 6-membered ring. Preferred examples of the tetravalent group having an aliphatic 4-membered ring or an aliphatic 6-membered ring include the following groups.

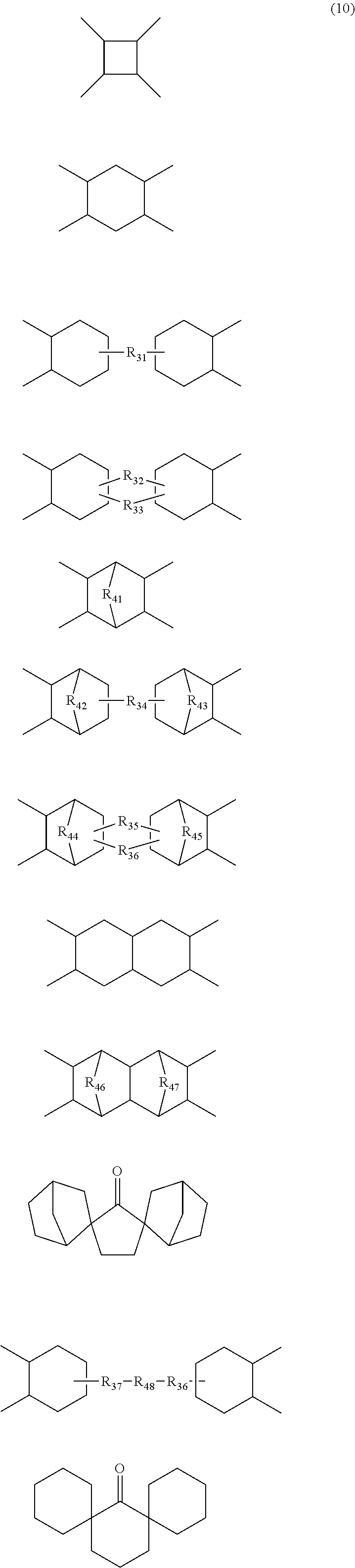

(wherein R₃₁ to R₃₈ are each independently a direct bond, or a divalent organic group; and R₄₁ to R₄₇ each independently represent one selected from the group consisting of groups represented by the formulas: —CH₂—, —CH═CH—, —CH₂CH₂—, —O— and —S—. R₄₈ is an organic group having an aromatic ring or an alicyclic structure.) Specific examples of R₃₁, R₃₂, R₃₃, R₃₄, R₃₅, R₃₆, R₃₇ and R₃₈ include a direct bond, or an aliphatic hydrocarbon group having 1 to 6 carbon atoms, or an oxygen atom (—O—), a sulfur atom (—S—), a carbonyl bond, an ester bond, and an amide bond.

Examples of the organic group having an aromatic ring as R₄₈ include the following groups.

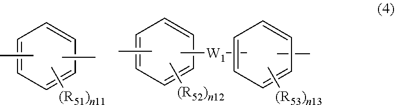

(wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group, a hydroxyl group, a carboxyl group, or a trifluoromethyl group.)

Specific examples of W₁ include divalent groups represented by the formula (5) as described below, and divalent groups represented by the formula (6) as described below.

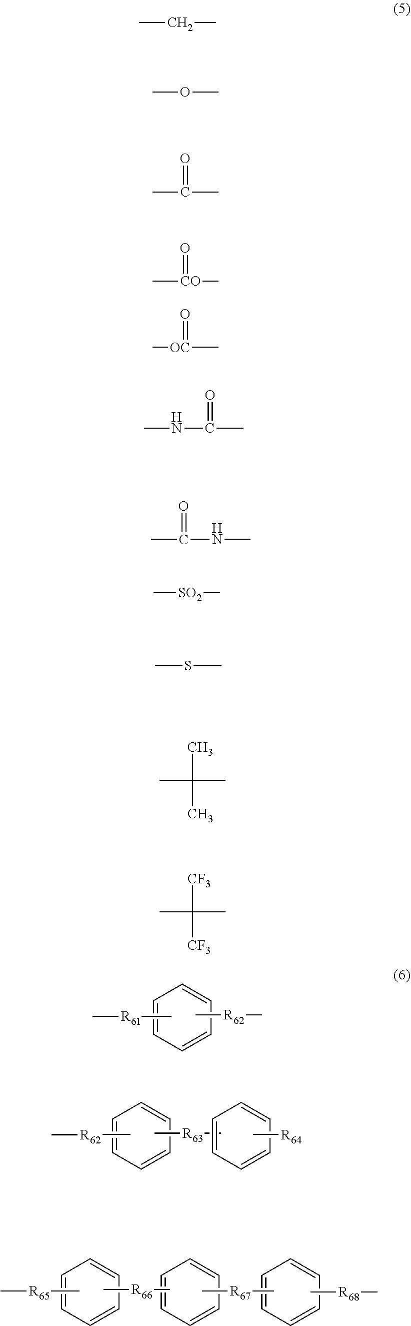

(wherein R₆₁ to R₆₈ in the formula (6) each independently represent any one of the divalent groups represented by the formula (5).)

Because the obtained polyimide may have high heat resistance, high light transmittance, and low coefficient of linear thermal expansion, the following groups are particularly preferred as the tetravalent group having an alicyclic structure.

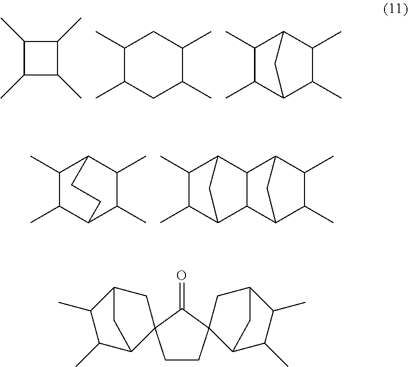

Examples of the tetracarboxylic acid component to provide a repeating unit of the chemical formula (II) in which X; is a tetravalent group having an alicyclic structure include 1,2,3,4-cyclobutane tetracarboxylic acid, isopropylidenediphenoxybisphthalic acid, cyclohexane-1,2,4,5-tetracarboxylic acid, [1,1′-bi(cyclohexane)]-3,3′,4,4′-tetracarboxylic acid, [1,1′-bi(cyclohexane)]-2,3,3′,4′-tetracarboxylic acid, [1,1′-bi(cyclohexane)]-2,2′,3,3′-tetracarboxylic acid, 4,4′-methylenebis(cyclohexane-1,2-dicarboxylic acid), 4,4′-(propane-2,2-diyl)bis(cyclohexane-1,2-dicarboxylic acid), 4,4′-oxybis(cyclohexane-1,2-dicarboxylic acid), 4,4′-thiobis(cyclohexane-1,2-dicarboxylic acid), 4,4′-sulfonyl bis(cyclohexane-1,2-dicarboxylic acid), 4,4′-(dimethylsilanediyl)bis(cyclohexane-1,2-dicarboxylic acid), 4,4′-(tetrafluoropropane-2,2-diyl)bis(cyclohexane-1,2-dicarboxylic acid), octahydropentalene-1,3,4,6-tetracarboxylic acid, bicyclo[2.2.1]heptane-2,3,5,6-tetracarboxylic acid, 6-(carboxymethyl) bicyclo[2.2.1]heptane-2,3,5-tricarboxylic acid, bicyclo[2.2.2]octane-2,3,5,6-tetracarboxylic acid, bicyclo[2.2.2]octa-5-ene-2,3,7,8-tetracarboxylic acid, tricyclo[4.2.2.02,5]decane-3,4,7,8-tetracarboxylic acid, tricyclo[4.2.2.02,5]deca-7-ene-3,4,9,10-tetracarboxylic acid, 9-oxatricyclo[4.2.1.02,5]nonane-3,4,7,8-tetracarboxylic acid, norbornane-2-spiro-α-cyclopentanone-α′-spiro-2″-norbornane-5,5″,6,6″-tetracarboxylic acid, (4arH,8acH)-decahydro-1t,4t:5c,8c-dimethanonaphthalene-2c,3c,6c,7c-tetracarboxylic acid, and (4arH,8acH)-decahydro-1t,4t:5c,8c-dimethanonaphthalene-2t,3t,6c,7c-tetracarboxylic acid, and derivatives thereof, including tetracarboxylic dianhydride, tetracarboxylic acid silyl ester, tetracarboxylic acid ester, and tetracarboxylic acid chloride. The tetracarboxylic acid component may be used alone or in combination of a plurality of types.

### <Y₁ and Diamine Component>

When Y₁ is a divalent group having an aromatic ring, preferred is a divalent group having an aromatic ring having 6 to 40 carbon atoms, more preferably 6 to 20 carbon atoms.

Examples of the divalent group having an aromatic ring include the following groups.

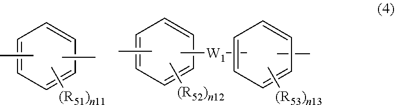

(wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group, a hydroxyl group, a carboxyl group, or a trifluoromethyl group.)

Specific examples of W₁ include divalent groups represented by the formula (5) as described below, and divalent groups represented by the formula (6) as described below.

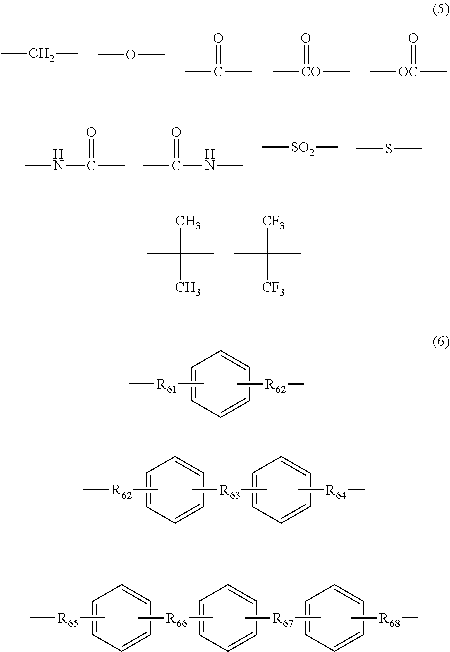

(wherein R₆₁ to R₆₈ in the formula (6) each independently represent any one of the divalent groups represented by the formula (5).)

Because the obtained polyimide may have high heat resistance, high light transmittance, and low coefficient of linear thermal expansion, W₁ is particularly preferably a direct bond, or one selected from the group consisting of groups represented by the formulas: —NHCO—, —CONH—, —COO— and —OCO—. In addition, W₁ is particularly preferably any one of the divalent groups represented by the formula (6) in which Rei to Res are a direct bond, or one selected from the group consisting of groups represented by the formulas: —NHCO—, —CONH—, —COO— and —OCO—.

In addition, preferred groups include a group in which W₁ in the above formula (4) is a fluorenyl-containing group represented by the following formula (3B):

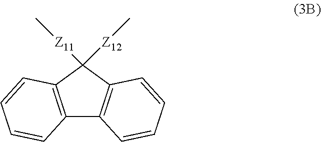

Z₁₁ and Z₁₂ are each independently, preferably the same, a single bond or a divalent organic group. Zn and Z₁₂ are preferably an organic group containing an aromatic ring, such as the formula (3B1):

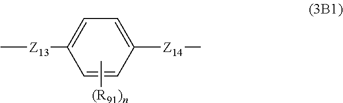

(Z₁₃ and Z₁₄ are each independently a single bond, —COO—, —OCO— or —O—, wherein when Z₁₄ is attached to a fluorenyl group, preferred is a structure in which Z₁₃ is —COO—, —OCO— or —O— and Z₁₄ is a single bond; R₉₁ is an alkyl group having 1 to 4 carbon atoms or a phenyl group, preferably methyl, and n is an integer of 0 to 4, and preferably 1.).

Another preferred group includes a compound in which W₁ in the above formula (4) is a phenylene group, that is, terphenyldiamine compounds, and particularly preferred are compounds in which all bondings are in para position.

Another preferred group includes a compound in which W₁ in the above formula (4) is a phenyl ring as depicted at first in formula (6) wherein R₆₁ and R₆₂ are 2,2-propylidene groups.

Still another preferred group includes a compound in which W₁ in the above formula (4) is represented by formula (3B2):

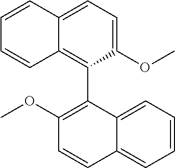

Examples of the diamine component to provide a repeating unit of the general formula (II) in which Y₁ is a divalent group having an aromatic ring include p-phenylenediamine, m-phenylenediamine, benzidine, 3,3′-diamino-biphenyl, 2,2′-bis(trifluoromethyl)benzidine, 3,3′-bis(trifluoromethyl)benzidine, m-tolidine, 4,4′-diaminobenzanilide, 3,4′-diaminobenzanilide. N,N′-bis(4-aminophenyl) terephthalamide, N,N′-p-phenylenebis(p-amino benzamide), 4-aminophenoxy-4-diaminobenzoate, bis(4-aminophenyl) terephthalate, biphenyl-4,4′-dicarboxylic acid bis(4-aminophenyl) ester, p-phenylenebis(p-aminobenzoate), bis(4-aminophenyl)-[1,1′-biphenyl]-4,4′-dicarboxylate, [1,1′-biphenyl]-4,4′-diyl bis(4-aminobenzoate), 4,4′-oxydianiline, 3,4′-oxydianiline, 3,3′-oxydianiline, p-methylenebis(phenylenediamine). 1,3-bis(4-aminophenoxy)benzene, 1,3-bis(3-aminophenoxy)benzene, 1,4-bis(4-aminophenoxy)benzene, 4,4′-bis(4-aminophenoxy) biphenyl, 4,4′-bis(3-amino phenoxy) biphenyl, 2,2-bis(4-(4-aminophenoxy)phenyl) hexafluoropropane. 2,2-bis(4-aminophenyl) hexafluoropropane, bis(4-aminophenyl) sulfone, 3,3′-bis(trifluoromethyl)benzidine, 3,3′-bis((aminophenoxy)phenyl) propane, 2,2′-bis(3-amino-4-hydroxyphenyl) hexafluoropropane, bis(4-(4-aminophenoxy) diphenyl) sulfone, bis(4-(3-aminophenoxy)diphenyl) sulfone, octafluorobenzidine, 3,3′-dimethoxy-4,4′-diaminobiphenyl, 3,3′-dichloro-4,4′-diaminobiphenyl, 3,3′-difluoro-4,4′-diaminobiphenyl, 2,4-bis(4-aminoanilino)-6-amino-1,3,5-triazine, 2,4-bis(4-aminoanilino)-6-methylamino-1,3,5-triazine, 2,4-bis(4-aminoanilino)-6-ethylamino-1,3,5-triazine, and 2,4-bis(4-amino anilino)-6-anilino-1,3,5-triazine. Examples of the diamine component to provide a repeating unit of the general formula (1) in which Y1 is a divalent group having a fluorine atom-containing aromatic ring include 2,2′-bis(trifluoromethyl)benzidine, 3,3′-bis(trifluoromethyl)benzidine, 2,2-bis[4-(4-aminophenoxy)phenyl]hexafluoropropane, 2,2-bis(4-aminophenyl) hexafluoropropane, and 2,2′-bis(3-amino-4-hydroxyphenyl) hexafluoropropane. In addition, preferred diamine compounds include 4,4′-(((9H-fluorene-9,9-diyl)bis([1,1′-biphenyl]-5,2-diyl))bis(oxy))diamine, [1,1′:4′,1″-terphenyl]-4,4″-diamine, 4,4′-([1,1′-binaphthalene]-2,2′-diylbis(oxy))diamine. The diamine component may be used alone or in combination of a plurality of types.

When Y₁ is a divalent group having an alicyclic structure, a divalent group having an alicyclic structure which has 4 to 40 carbon atoms is preferred, and it is more preferred that the group has at least one aliphatic 4- to 12-membered ring, more preferably an aliphatic 6-membered ring.

Examples of the divalent group having an alicyclic structure include the following groups.

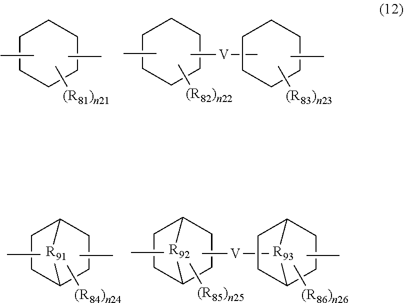

(wherein V₁ and V₂ are each independently a direct bond, or a divalent organic group; n₂₁ to n₂₆ each independently represent an integer of 0 to 4; R₈₁ to R₈₆ are each independently an alkyl group having 1 to 6 carbon atoms, a halogen group, a hydroxyl group, a carboxyl group, or a trifluoromethyl group; and R₉₁, R₉₂ and R₉₃ are each independently one selected from the group consisting of groups represented by the formulas: —CH₂—, —CH═CH—, —CH₂CH₂—, —O— and —S—) Specific examples of V₁ and V₂ include a direct bond and divalent groups represented by the formula (5) as described above.

Because the obtained polyimide may have both high heat resistance and low coefficient of linear thermal expansion, the following group is particularly preferred as the divalent group having an alicyclic structure.

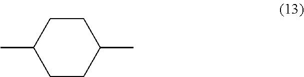

Among them, the following group is preferred as the divalent group having an alicyclic structure.

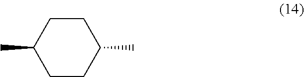

Examples of the diamine component to provide a repeating unit of the general formula (II) in which Y₁ is a divalent group having an alicyclic structure include 1,4-diaminocyclohexane, 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane, 1,2-diaminocyclohexane, 1,3-diamino cyclobutane, 1,4-bis(aminomethyl)cyclohexane, 1,3-bis(aminomethyl) cyclohexane, diaminobicycloheptane, diaminomethylbicycloheptane, diaminooxybicycloheptane, diaminomethyloxybicycloheptane, isophoronediamine, diaminotricyclodecane, diaminomethyltricyclodecane, bis(aminocyclohexyl) methane, bis(aminocyclohexyl) isopropylidene, 6,6′-bis(3-aminophenoxy)-3,3,3′,3′-tetramethyl-1,1′-spirobiindane, and 6,6′-bis(4-aminophenoxy)-3,3,3′,3′-tetramethyl-1,1′-spirobiindane. The diamine component may be used alone or in combination of a plurality of types.

Among these tetracarboxylic acid derivatives, 3,3′,4,4′-biphenyltetracarboxylic dianhydride is particularly preferred, and among diamine compounds, p-phenylenediamine is particularly preferred. It is particularly preferable that the proportion of 3,3′,4,4′-biphenyltetracarboxylic dianhydride in all tetracarboxylic acid components is 60 mol % or more, and the amount of p-phenylenediamine in all diamine components is 60 mol % or more.

### <Production of Polyimide Precursor>

In order to produce the polyimide precursor of the present invention, the process includes at least a polymerization step of reacting a tetracarboxylic acid component (preferably a tetracarboxylic dianhydride) and a diamine component in an organic solvent so that the weight average molecular weight (Mw) of the polyimide precursor becomes as described above (i.e. preferably 80,000 or more and 300,000 or less).

Examples of the solvent include, but not limited to, used in the production of the polyimide precursor, amide solvents such as N, N-dimethylformamide, N,N-dimethylacetamide, N, N-diethylacetamide, N, N-dimethylpropionamide, 3-methoxy-N, N-dimethylpropanamide, N-methyl-2-pyrrolidone, N-ethyl-2-pyrrolidone, and N-vinyl-2-pyrrolidone; cyclic ester solvents such as γ-butyrolactone, γ-valerolactone, δ-valerolactone, γ-caprolactone, ε-caprolactone and α-methyl-γ-butyrolactone; carbonate solvents such as ethylene carbonate and propylene carbonate: glycol solvents such as triethylene glycol: phenol solvents such as m-cresol, p-cresol, 3-chlorophenol and 4-chlorophenol; acetophenone, 1,3-dimethyl-2-imidazolidinone, sulfolane, dimethylsulfoxide, and the like. In addition, other common organic solvents, for example, alcohol solvents such as methanol and ethanol, and phenol, o-cresol, butyl acetate, ethyl acetate, isobutyl acetate, propyleneglycol methyl acetate, ethyl cellosolve, butyl cellosolve, 2-methyl cellosolve acetate, ethyl cellosolve acetate, butyl cellosolve acetate, tetrahydrofuran, dimethoxyethane, diethoxyethane, dibutyl ether, diethylene glycol dimethyl ether, methyl isobutyl ketone, diisobutyl ketone, cyclopentanone, cyclohexanone, methyl ethyl ketone, acetone, butanol, ethanol, xylene, toluene, chlorobenzene, N-methylcaprolactam, hexamethylphosphorotriamide, bis(2-methoxyethyl) ether, 1,2-bis(2-methoxyethoxy) ethane, bis[2-(2-methoxyethoxy)ethyl]ether, 1,4-Dioxane, dimethyl sulfoxide, dimethyl sulfone, diphenyl ether, diphenyl sulfone, tetramethylurea, anisole, turpentine, mineral spirits, petroleum naphtha-based solvents, biodegradable solvent such as methyl lactate, ethyl lactate, and butyl lactate and the like may be used. The organic solvents used may be one or two or more types.

When carrying out a polymerization reaction to obtain a polyimide precursor, the concentration of all monomers in an organic solvent (substantially equal to the solid content concentration of the polyimide precursor solution) may be appropriately selected depending on the purpose of use and production. The solid content concentration of the resulting polyimide precursor solution is, for example, 30% by mass or less, preferably 20% by mass or less, and in one preferred embodiment. 15% by mass or less, based on the total amount of the polyimide precursor and solvent. However, if the solid content concentration is too low, productivity and handling during use may deteriorate, and therefore, it is preferably 2% by mass or more, more preferably 5% by mass or more.

As a polyimide precursor solution for film production, a polyimide precursor solution produced at an above concentration may be used as it is, or may be diluted or concentrated as necessary. It is also preferable to set to 5 to 20% by mass for film production by cast coating.

Further, the solution viscosity of the polyimide precursor solution at 30° C., is not particularly limited, but in view of handling, it is preferably 1000 Pa·s (10,000 Poise) or less, more preferably 500 Pa·s or less, even more preferably 500 Pa·s or less, particularly preferably 400 Pa·s or less, and more preferably 0.1 Pa·s or more, further preferably 0.5 Pa·s or more, particularly preferably 1 Pa·s or more. If the solution viscosity exceeds 1000 Pa·s, fluidity may be lost and it may be difficult to apply uniformly to a carrier substrate such as metal or glass, and if the solution viscosity is less than 0.1 Pa·s dragging or repelling may occur when coating onto a carrier substrate, and it may be difficult to obtain a polyimide film with good properties. A polyimide precursor solution manufactured with such a viscosity may be used as it is, or may be diluted or concentrated as necessary. It is also preferable to set to 1 to 20 Pa·s (10 to 200 Poise) for film production by cast coating.

An example of the method for producing the polyimide precursor of the present invention will be explained. In order for the polyimide precursor to have a preferable weight average molecular weight, it is preferable to contain at least polyamic acid. In addition, all the tetracarboxylic acid components and all the diamine components that make up the polyimide precursor satisfy the equation:

$$1 \leq X / Y \leq 1. 05$$

(Herein, X represents number of moles of a tetracarboxylic acid component, and Y represents number of moles of a diamine component.).
X/Y is more preferably 1.02 or less, even more preferably 1.01 or less, and is also very preferably equal to 1. These ranges are preferably applied when no dicarboxylic acid anhydride is used, and are preferably satisfied in the following production methods (1) to (4).
(1) An example of a method for producing a polyimide precursor includes a method comprising reacting tetracarboxylic dianhydride(s) and diamine compound(s) in an organic solvent to polymerize in such amounts that the X/Y range is as described above, preferably in substantially equimolar amounts, whereby producing a solution of a polyimide precursor that is a polyamic acid. The reaction temperature is not limited, but is, for example, 25° C., or higher, preferably higher than 40° C., for example 100° C., or lower, preferably 80° C., or lower, more preferably 70° C., or lower, and the reaction time is about 0.2 hours or longer, preferably 2 hours or longer, and about 60 hours or less, preferably 48 hours or less.
(2) A further different example of the method for producing a polyimide precursor includes a method comprising: a first step of reacting a tetracarboxylic dianhydride with a slightly excess amount of a diamine compound to produce an amine-terminated polyamic acid; and a second step of adding an acid. In this method, in the first step, the molecular weight of the amine-terminated polyamic acid can be adjusted by adjusting the ratio of the tetracarboxylic dianhydride and the diamine compound. The ratio of all tetracarboxylic acid components and all diamine components used is set so as to fall within the above-mentioned X/Y range, preferably substantially equimolar. Namely, moles of the tetracarboxylic acid added in the second step is adjusted equal to the moles of the excess diamine compound in the first step. As a result, the amount of functional groups at the terminals of the polyimide after imidization can be made substantially zero.

The reaction temperature is not limited, but is, for example, 25° C., or higher, preferably higher than 40° C., for example 100° C., or lower, preferably 80° C., or lower, more preferably 70° C., or lower, and the reaction time is about 0.2 hours or longer, preferably 2 hours or longer, and preferably about 60 hours or less, more preferably 48 hours or less.
(3) A further different example of the method for producing a polyimide precursor includes a method comprising: a first step of producing a carboxylic acid-terminated polyamic acid and a second step of producing a diamine-terminated polyamic acid. In the first step, for example, in an organic solvent, a diamine compound and a slightly excess amount of tetracarboxylic dianhydride are reacted to produce an anhydride-terminated polyamic acid, and then the anhydride group is hydrolyzed to obtain a carboxylic acid-terminated polyamic acid. Water for hydrolysis may be added together with the organic solvent from the beginning, or may be newly added after the reaction of the diamine compound and the tetracarboxylic dianhydride. In the second step, a tetracarboxylic dianhydride and a slightly excess amount of a diamine compound are further added to produce a diamine-terminated polyamic acid.

In the first step and the second step, by adjusting the ratio of the tetracarboxylic dianhydride and the diamine compound, the molecular weights of the carboxylic acid-terminated polyamic acid and the amine-terminated polyamic acid can be adjusted. That is, the weight average molecular weight of the polyimide precursor of the present invention can be adjusted. In addition, by setting the ratio of all tetracarboxylic acid components and all diamine components to be within the above-mentioned X/Y range, preferably substantially equimolar, the amount of the functional groups at the terminals of the polyimide after imidization can be made substantially zero.

In addition, although an example has been described in which the first step and the second step are performed continuously in one reaction container, the polyimide precursor solution of the present invention can also be prepared by performing the first step and the second step in separate reaction containers, and mixing the resulting polyamic acid solutions together. The reaction temperature in the first step and the second step is not limited, but is, for example, 25° C., to 100° C., preferably higher than 40° C., for example, 80° C., or lower, preferably 70° C., or lower, and the reaction time is about 0.2 hours or longer, preferably 2 hours or longer, and preferably about 60 hours or less, more preferably 48 hours or less.
(4) An example of a different method for producing a polyimide precursor includes a method in which (2) is combined with the above (3). For example, when producing carboxylic acid-terminated polyamic acid and amine-terminated polyamic acid in the first and second steps of (3) above, both components are adjusted so that the amount of diamine in the polyamic acid produced in the second process is excess. And as a third step (corresponding to the second step of (2)), tetracarboxylic acid is added. The ratio of all tetracarboxylic acid components and all diamine components used is set to be within the above-mentioned X/Y range, preferably substantially equimolar, which is the same as above and the reaction temperature and time are also the same.
(5) Another example of a method for producing a polyimide precursor includes a production method comprising adding and reacting a carboxylic acid monoanhydride in addition to a tetracarboxylic acid component and a diamine component. The carboxylic acid monoanhydride is particularly preferably a dicarboxylic acid monoanhydride, and may be an aromatic carboxylic acid monoanhydride or an aliphatic carboxylic acid monoanhydride. Particularly preferred are aromatic carboxylic acid monoanhydrides. The aromatic carboxylic acid monoanhydride preferably has an aromatic ring having 6 to 30 carbon atoms, more preferably has an aromatic ring having 6 to 15 carbon atoms, and more preferably has an aromatic ring having 6 to 10 carbon atoms.

Examples of carboxylic acid monoanhydrides include aromatic carboxylic acid monoanhydrides such as phthalic anhydride, 2,3-benzophenonedicarboxylic anhydride, 3,4-benzophenonedicarboxylic anhydride, 1,2-naphthalenedicarboxylic anhydride, 2,3-naphthalenedicarboxylic anhydride, 1,8-naphthalenedicarboxylic anhydride, 1,2-anthracenedicarboxylic anhydride, 2,3-anthracenedicarboxylic anhydride, and 1,9-anthracenedicarboxylic anhydride; and maleic anhydride, succinic anhydride, alicyclic carboxylic acid monoanhydrides such as tetrahydrophthalic anhydride, hexahydrophthalic anhydride, itaconic anhydride, and trimellitic anhydride. Among these, phthalic anhydride is preferred.

When adding a carboxylic acid monoanhydride, it is more preferable that the following equations (1) and (2) are satisfied.

$$0.97 \leq X / Y < 1. \qquad Equation ( 1 )$$

$$1. \leq ( X + Z / 2 ) / Y \leq 1.05 \qquad Equation ( 2 )$$

(In the equation, X represents number of moles of the tetracarboxylic acid component, Y represents number of moles of the diamine component, and Z represents number of moles of the carboxylic acid monoanhydride.)

When X/Y is 0.97 or more, the molecular weight of the polyimide precursor (especially polyamic acid) is increased, and the strength and heat resistance of the resulting polyimide film are improved. X/Y is preferably 0.98 or more. When X/Y is less than 1.00, the diamine component becomes excessive with respect to the tetracarboxylic acid component, and an amino group is formed that can be end-capped with a carboxylic acid monoanhydride. By appropriately adjusting X/Y, the weight average molecular weight of the obtained polyamic acid can be adjusted.

In addition, when (X+Z/2)/Y is 1 or more, it means that all amino groups are end-capped with carboxylic acid monoanhydride or that no amino groups remain after imidization, which improves the charge-up property. (X+Z/2)/Y is more preferably 1.02 or less, even more preferably 1.01 or less. If it is closer to 1, the amount of free carboxylic acid monoanhydride is less, and strength of the obtained polyimide film and charge-up characteristics can be improved.

In the case of the production method involving the addition of a carboxylic acid monoanhydride, generally preferred is a method comprising a first step of reacting a tetracarboxylic acid component and a diamine component in a solvent at a molar ratio that preferably satisfies the above-mentioned equation (1) to obtain a polyimide precursor (especially polyamic acid) having an amino group at its terminal; and a second step of adding and reacting a carboxylic acid monoanhydride at a molar ratio that preferably satisfies the above equation (2), to end-cap the polyimide precursor (especially polyamic acid).

The first step is carried out at a relatively low temperature of, for example, 100° C., or lower, preferably 80° C., or lower, in order to suppress the imidization reaction. Although not limited, the reaction temperature is usually 25° C., or higher, preferably 40° C., or higher, more preferably 50° C., or higher, and usually 100° C., or lower, preferably 80° C., or lower, and the reaction time is usually about 0.1 hour or longer, preferably about 2 hours or longer, and usually about 24 hours or less, preferably about 12 hours or less. By controlling the reaction temperature and reaction time within the above ranges, a solution composition of a high molecular weight polyimide precursor can be efficiently obtained. Although the reaction can be carried out under an air atmosphere, it is usually carried out under an inert gas atmosphere, preferably under a nitrogen gas atmosphere.

In the second step, the reaction temperature may be set appropriately, but from the viewpoint of reliably end-capping the ends of the polyimide precursor, it is preferably 25° C., or higher, preferably 70° C., or lower, more preferably 60° C., or lower, and further preferably 50° C., or lower. The reaction time is usually about 0.1 hour or longer and about 24 hours or less.

If necessary, an imidization catalyst, an organic phosphorus-containing compound, inorganic fine particles, and the like may be added to the polyimide precursor solution in the case of thermal imidization. If necessary, a cyclization catalyst, a dehydrating agent, inorganic fine particles, and the like may be added to the polyimide precursor solution in the case of chemical imidization. Inorganic fine particles may be added to the polyimide solution, if necessary.

The imidization catalyst may be a substituted or unsubstituted nitrogen-containing heterocyclic compound, an N-oxide compound of the nitrogen-containing heterocyclic compound, a substituted or unsubstituted amino acid compound, an aromatic hydrocarbon compound having a hydroxyl group, or an aromatic heterocyclic compound. Examples include especially lower alkylimidazole, such as 1,2-dimethylimidazole, N-methylimidazole, N-benzyl-2-methylimidazole, 2-methylimidazole, 2-ethyl-4-methylimidazole, and 5-methylbenzimidazole: benzimidazoles such as N-benzyl-2-methylimidazole; phenylimidazoles such as 2-phenylimidazole; substituted pyridines such as isoquinoline, 3,5-dimethylpyridine, 3,4-dimethylpyridine, 2,5-dimethylpyridine, 2,4-dimethylpyridine, and 4-n-propylpyridine. The amount of the imidization catalyst to be used is preferably 0.01 times equivalent or more, especially about 0.02 times equivalent or more, and 2 times equivalent or less, especially about 1 times equivalent or less, based on the amide acid unit of the polyamide acid. By using an imidization catalyst, the physical properties of the resulting polyimide film, particularly elongation and end tear resistance, may be improved.

Examples of organic phosphorus-containing compounds include phosphoric acid esters such as monocaproyl phosphate, monooctyl phosphate, monolauryl phosphate, monomyristyl phosphate, monocetyl phosphate, monostearyl phosphate, phosphoric acid monoester of triethylene glycol monotridecyl ether, phosphoric acid monoester of tetraethylene glycol monolauryl ether, phosphoric acid monoester of diethylene glycol monostearyl ether, dicaproyl phosphate, dioctyl phosphate, dicapryl phosphate, dilauryl phosphate, dimyristyl phosphate, dicetyl phosphate, distearyl phosphate, phosphoric acid diester of tetraethylene glycol mononeopentyl ether, phosphoric acid diester of triethylene glycol monotridecyl ether, phosphoric acid diester of tetraethylene glycol monolauryl ether, and phosphoric acid diester of diethylene glycol monostearyl ether, and phosphoric acid triester, for example, trimethyl phosphate and triphenyl phosphate, and amine salts of these phosphoric acid esters. The amines include ammonia, monomethylamine, monoethylamine, monopropylamine, monobutylamine, dimethylamine, diethylamine, dipropylamine, dibutylamine, trimethylamine, triethylamine, tripropylamine, tributylamine, monoethanolamine, diethanolamine, triethanolamine, and the like.

Examples of cyclization catalysts include aliphatic tertiary amines such as trimethylamine and triethylenediamine, aromatic tertiary amines such as dimethylaniline, and heterocyclic tertiary amines such as isoquinoline, pyridine, α-picoline, and β-picoline.

Examples of the dehydrating agent include aliphatic carboxylic anhydrides such as acetic anhydride, propionic anhydride, and butyric anhydride, and aromatic carboxylic acid anhydrides such as benzoic anhydride.

Examples of inorganic fine particles include inorganic oxide powders in a form of particle such as titanium dioxide powder, silicon dioxide (silica) powder, magnesium oxide powder, aluminum oxide (alumina) powder, and zinc oxide powder: inorganic nitride powders in a form of particle such as silicon nitride powder, and titanium nitride powder; inorganic carbide powders such as silicon carbide powders, and inorganic salt powders in a form of particle such as calcium carbonate powders, calcium sulfate powders, and barium sulfate powders. Two or more types of these inorganic fine particles may be used in combination. In order to uniformly disperse these inorganic fine particles, any means that are publicly known per se can be used.

In one embodiment, the polyimide precursor solution is preferably free of silane coupling agents such as alkoxysilanes. In a polyimide film obtained using a silane coupling agent, the silane coupling agent may bleed out. This causes problems such as a decrease in the charge-up characteristics of the polyimide film (a decrease in the LR ratio), a decrease in adhesive strength, and swelling of the laminate. Furthermore, when a silane coupling agent is added to or reacted with a polyimide precursor solution, there is also a problem that the viscosity stability of the polyimide precursor solution decreases. In order to avoid these problems, it is preferable not to use a silane coupling agent.

In the manner described above, a high molecular weight polyimide precursor, particularly preferably a polyamic acid, is finally obtained.

Further, in the present invention, it is preferable that the polyimide produced from the polyimide precursor satisfies the characteristics shown in the following embodiments.

In one embodiment of the present invention, the weight fraction of imide groups (—C(O)NC(O)—) in the polyimide repeating unit (i.e., above-mentioned general formula II) is preferably less than 38.3% by weight. In certain embodiments, it is more preferably 30% by weight or less.

Here, the polyimide may be a copolymer, that is, at least one of the tetracarboxylic acid component and the diamine component that provides the polyimide may contain two or more types of compounds. In this case, the weight fraction of imide groups is calculated as a weighted average based on the supplied monomer ratio. The weight fraction of groups other than imide groups is calculated in the same way. In the following description, when referring to the weight fraction of a particular group, polyimide includes both homopolymers and copolymers.

In one embodiment of the present invention, the weight fraction of functional groups in the polyimide repeating unit is preferably small. The “functional group in the repeating unit” defined here is a portion other than the aromatic ring and saturated alkyl chain in the polyimide repeating unit, and included —O— (ether bond), —CO— (carbonyl group), —COO— (ester), —SO2-, and the like. F and Cl substituting hydrogens in aromatic rings and saturated alkyl chains are not included in the “functional group in the repeating unit.”

It is also preferable that the total amount of the imide group and the “functional group in the repeating unit” is less than 38.3% by weight in the polyimide repeating unit, more preferably 30% by weight or less, further preferably 25% by weight or less.

In addition, in one embodiment of the present invention, it is preferable that the content of the functional group other than the above is small, regardless of whether it is present in the polyimide repeating unit, is present at the terminal, or is another compound. It is also very preferable that they are not included at all. Examples of such undesired functional groups include Si-containing groups (siloxane bond, silyl group, and the like).

In a preferred embodiment of the present invention, the tetracarboxylic acid component forming the repeating unit preferably comprises a compound selected from tetracarboxylic dianhydrides having a fluorene structure in the molecule, and a tetracarboxylic dianhydrides having three or more benzene rings per one functional group other than two acid anhydride groups (corresponding to the above-mentioned “functional group in the repeating unit”). In addition, a compound having no functional group corresponding to the “functional group in the repeating unit” other than the two acid anhydride groups is also included in the preferable compounds. In this case, number of benzene rings is preferably 2 or more and more preferably 3 or more.

In a preferred embodiment of the present invention, the diamine component forming the repeating unit preferably comprises a compound selected from diamines having a fluorene structure in the molecule, and diamines having three or more benzene rings per one functional group other than two amine groups (corresponding to the above-mentioned “functional group in repeating unit”). In addition, a compound having no functional group corresponding to the “functional group in the repeating unit” other than two amine groups is also included in the preferable compounds. In this case, number of benzene rings is preferably 2 or more and more preferably 3 or more.

In a preferred embodiment of the present invention, each of the tetracarboxylic acid component and the diamine component forming the repeating unit preferably comprises compounds selected from the above-mentioned conditions, that is, from compounds having a fluorene structure in the molecule and compounds having three or more benzene rings per one “functional group in the repeating unit” (including the case of having no functional group).

In one aspect of the present invention, it is also preferable that the “amount of terminal functional group” is small. “Amount of terminal functional group” is calculated based on the feeding ratio of a tetracarboxylic acid component and a diamine component when producing a polyimide (when producing a polyamic acid), the purity of each component, an addition amount of the terminal capping agent, and a reactive additive. The calculation of the amount of the terminal functional group based on the feed ratio of the tetracarboxylic acid component and the diamine component is carried out as follows.

Since the degree of polymerization of the polyimide obtained with “tetracarboxylic dianhydride/diamine ratio=1” is theoretically ∞ (infinite), the amount of the terminal group is 1/∞=0. If the feeding amount of tetracarboxylic dianhydride and diamine are not equimolar, and the amount of diamine is excessive, the polyimide having a structure of the formula (II-B) and having a polymerization degree of n can be theoretically obtained, n can be obtained by determining n that satisfies:

tetracarboxylic dianhydride/diamine ratio=n/(n+1). (Equation)

When the formula weight of the repeating unit is “a” and the molecular weight of one terminal diamine is “a_{b}”, the formula weight of a polyimide having a degree of polymerization of n is (a*n+a_{b}). Therefore, the amount of terminal amine is determined by:

$$2 / ( a * n + {a}_{b} ) [ unit : mol / g ] .$$

In the examples of the present application, it is expressed in μmol/g.

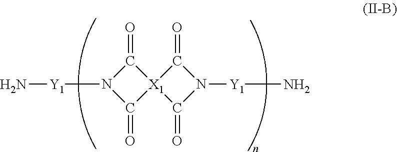

In one embodiment of the present invention, the amount of terminal amine groups is preferably 30 μmol/g or less, more preferably 20 μmol/g or less, still more preferably 10.5 μmol/g or less. Further, in a different aspect of the present invention, the total amount of functional groups at the terminals is preferably 30 μmol/g or less, more preferably 20 μmol/g or less, still more preferably 10.5 μmol/g or less.

In a preferred embodiment of the present invention, it is preferable that the total weight ratio of the imide group and the “functional group in the repeating unit” is 30% by weight or less and the “amount of terminal functional group” is 20 μmol/g or less. In another preferred embodiment, it is preferable that the total weight ratio of the imide group and the “functional group in the repeating unit” is 40% by weight or less and the “amount of terminal functional group” is 10.5 μmol/g or less. It is also very preferable that the total weight ratio of the imide group and the “functional group in the repeating unit” is 30% by weight or less and the “amount of terminal functional group” is 10.5 μmol/g or less.

Control of the functional groups (imide group, functional group in repeating unit, terminal functional group) in polyimide as described above is an element that should be considered in order to obtain a polyimide having the charge-up characteristics of the present invention.

### <<Method for Manufacturing Polyimide Film>>

A method for manufacturing polyimide, particularly a method for manufacturing a polyimide film via a laminate having a polyimide film formed on a carrier substrate, will be described below.

Examples of a process for manufacturing a polyimide film generally include:
(1) a process comprising flow-casting, on a carrier substrate, a polyimide precursor (particularly polyamic acid) solution, or a polyimide precursor solution composition containing, as necessary, additives selected from an imidization catalyst, a dehydrating agent, and inorganic fine particles in a polyimide precursor solution, and heating to perform cyclodehydration and removal of a solvent to give a polyimide film (thermal imidization); and
(2) a process comprising flow-casting, on a carrier substrate, a polyimide precursor solution composition containing a cyclization catalyst and a dehydrating agent and, as necessary, a further selected additive such as inorganic fine particles in a polyimide precursor (particularly polyamic acid) solution; and then chemically cyclodehydrating it and heating to perform removal of a solvent and imidization to give a polyimide film (chemical imidization).

### <Production of Laminate and Electronic Device>

In the production of an electronic device, first, a polyimide film is formed by casting a polyimide precursor solution (including a composition solution containing an additive if necessary) on a carrier substrate, heat-treating it for imidization and desolvation (mainly desolvation in the case of a polyimide solution) to obtain a laminate of a carrier substrate and a polyimide film. The carrier substrate is not limited, but generally, a glass substrate of soda lime glass, borosilicate glass, non-alkali glass or the like, or a metal substrate of iron, stainless steel, copper or the like is used. The method for casting the polyimide precursor solution and the polyimide solution on the carrier substrate is not particularly limited, and examples thereof include conventionally known methods such as spin coating, screen printing, bar coating, and electrodeposition. The heat treatment conditions when the polyimide precursor solution is used are not particularly limited, but the treatment is carried out, after dried in the temperature range of 50° C., to 150° C., at the maximum heating temperature of, for example, 150° C., or higher, preferably 200° C., or higher, more preferably 250° C.′, and, for example, 600° C., or less, preferably 550° C., or less, more preferably 500° C., or less. The heat treatment conditions when the polyimide solution is used are not particularly limited, but the maximum heating temperature is, for example, 100° C., or higher, preferably 150° C., or higher, more preferably 200° C., or higher, and for example, 600° C., or less preferably 500° C., or less, more preferably 450° C., or less.

The thickness of the polyimide film is preferably 1 μm or more. When the thickness is less than 1 μm, the polyimide film cannot retain sufficient mechanical strength, and when used as a flexible device substrate, it may not be able to withstand stress and may be destroyed. The thickness of the polyimide film is preferably 20 μm or less. If the thickness of the polyimide film exceeds 20 μm, it becomes difficult to reduce the thickness of the flexible device. The thickness of the polyimide film is more preferably 2 to 10 μm in order to make the film thinner while maintaining sufficient resistance as a flexible device.

The obtained polyimide film is firmly laminated on the glass substrate. The peel strength between the glass substrate and the polyimide film is generally 50 mN/mm or more, preferably 100 mN/mm or more, more preferably 200 mN/mm or more, even more preferably 300 mN/mm or more, when measured according to JIS K6854-1.

A flexible device substrate may be formed by forming/laminating a second layer such as a resin film or an inorganic film on the obtained polyimide film. In particular, an inorganic film is suitable because it is used as a water vapor barrier layer. Examples of the water vapor barrier layer include inorganic films containing an inorganic material selected from the group consisting of metal oxides, metal nitrides and metal oxynitrides such as silicon nitride (SiNₓ), silicon oxide (SiOₓ), silicon oxynitride (SiOₓN_{y}), aluminum oxide (Al₂O₃), titanium oxide (TiO₂), and zirconium oxide (ZrO₂). Generally, as methods of forming these thin films, physical vapor deposition methods such as vacuum vapor deposition method, sputtering method and ion plating method, and chemical vapor deposition methods such as plasma CVD method and catalytic chemical vapor deposition (Cat-CVD) method and the like are known. This second layer may also be multi-layered. Even in the case of the device having the second layer on the polyimide film, the influence of the polyimide film may reach the semiconductor layer through the second layer. Therefore, to improve the device characteristics and the durability, the polyimide having good charge-up characteristics of the present invention is preferably used.

A flexible device substrate may be formed by laminating a polyimide film on a resin film or an inorganic film. A polyimide film may be laminated on a resin film or an inorganic film by using the polyimide precursor solution or the polyimide solution in the same manner as in the case of a carrier substrate.

The polyimide film obtained by the present invention is firmly laminated even when the inorganic film serves as a substrate. The peel strength between the polyimide film and the inorganic film (e.g., silicon oxide film) is generally 20 mN/mm or more, preferably 30 mN/mm or more, and more preferably 40 mN/mm or more, yet more preferably 50 mN/mm or more, when measured according to JIS K6854-1.

In manufacturing an electronic devices, elements and circuits necessary for the device are formed on the obtained laminate (particularly, on the polyimide film). The elements and circuits to be formed and the manufacturing process thereof differ depending on the type of device. When manufacturing an organic EL or a liquid crystal display device with a TFT, a TFT of, for example, amorphous silicon is formed on a polyimide film. The TFT includes, for example, a gate metal layer, a semiconductor layer such as an amorphous silicon film, a silicon nitride gate dielectric layer, and an ITO pixel electrode. Further, a structure required for an organic EL or a liquid crystal display can be formed thereon by a known method. Since the polyimide film obtained in the present invention is excellent in various characteristics such as heat resistance and toughness, the method for forming a circuit or the like is not particularly limited.

When a flexible device is intended as an electronic device, a device substrate (particularly a polyimide film) having a circuit or the like formed on its surface is peeled from a carrier substrate. The peeling method is not particularly limited, and for example, laser peeling in which a carrier substrate side is irradiated with a laser or the like for peeling, mechanical peeling in which peeling is performed mechanically, or the like can be performed.

The polyimide and the polyimide film of the present invention (including those on which a second layer such as a resin film or an inorganic film is formed/laminated) are particularly suitable as a substrate of an electronic device which is desired to be thin and flexible. The term “flexible (electronic) device” as used herein means that the device itself is flexible, and a semiconductor layer (transistor, diode, etc, as an element) is usually formed on the substrate to complete the device. It does not mean, for example, a COF (Chip On Film) in which a “hard” semiconductor element such as an IC chip is mounted on a conventional FPC (flexible printed wiring board). Examples of flexible (electronic) devices to which the polyimide and polyimide film of the present invention described above and below are preferably used include display devices such as liquid crystal displays, organic EL displays and electronic paper, and light receiving devices such as solar cells and CMOS.

The polyimide of the present invention can be used in various applications, but in order to exert the effect of excellent charge-up characteristics, it is preferably used in a device in which the polyimide and the semiconductor are in direct contact with each other or in a device in which they are laminated via a thin film (for example, a thin film of 200 nm or less, preferably 100 nm or less; for example, the above-mentioned second layers).

Further, in the above description, a method of forming an element or a circuit on the laminate of a polyimide film-carrier substrate has been described, but if there is no hindrance to the formation of the element or the circuit, elements and circuits may be formed on a single-layer polyimide film.

Examples of the semiconductor include silicon such as single crystal silicon, amorphous silicon, and polysilicon (which may be doped with an impurity for p-type or n-type), and gallium nitride-based compound semiconductors or other compound semiconductors.

### EXAMPLES

Hereinafter, the present invention will be described in more detail with reference to examples. The present invention is not limited to the examples below. The method of measuring the characteristics used in the following examples is shown below.

### <Evaluation of Varnish>

### (1) Viscosity

The viscosity was measured using an E-type viscometer at a measurement temperature of 23° C., 25° C., or 30° C.

### (2) Measurement of Weight Average Molecular Weight

The weight average molecular weight was measured under the following conditions.
Equipment: Tosoh HLC-8320GPC
Column: Tosoh TSKgel Super AWM-H 9 μm 6.0 mmI. D.×15 cm
Eluent: NMP (10 mmol/L LiCl, 30 mmol/L phosphoric acid)
Measurement temperature: 40° C.
Flow rate: 0.5 mL/min
Detection method: RI
Measurement amount: 20 μL

### <Measurement Method of SHG Characteristics>

### (1) Evaluation Sample

As shown in FIG. 1, a polyimide film 1 (10 μm thick) was formed on a glass substrate 3 to prepare a polyimide/glass laminate. Silver electrodes 2a and 2b were formed on the polyimide surface of the polyimide/glass laminate so that the distance between the electrodes was 50 μm to prepare a measurement sample.

### (2) SHG Measurement Conditions

While applying a voltage between the silver electrodes of the device shown in FIG. 1, the SH light generated when laser was irradiated from the glass side was detected. The laser conditions, voltage conditions, and detection wavelength conditions for the measurements are as follows.
Laser: 920 nm, 80 fs, 1 KHz, 10-15 mW, irradiated from the glass wafer side
Applied voltage waveform: rectangular wave, duty ratio 0.5, between 0V and +50V, 1 kHz
SH light detection wavelength: 460 nm
SH light measurement position: Measured on polyimide film in the range of 0 to 4 μm at the electrode end

### (3) SHG Evaluation

The intensity before voltage application was subtract as a baseline from the SHG light intensity near both electrodes (in the range of 0 to 4 μm) when voltage is applied. The smaller value was divided by the larger value to calculate the symmetry ratio (LR ratio). When this ratio was 0.5 or more, it was marked as ∘ (pass), and when it was below, it was marked as x (fail)

Monomers and solvents used in Examples and Comparative Examples are shown.

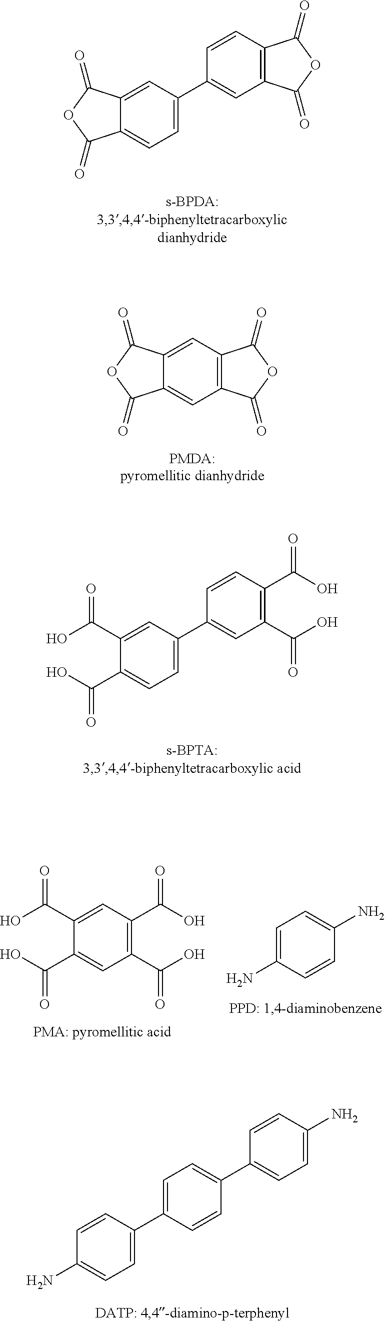 [SMILES: O=C1OC(=O)c2cc(-c3ccc4c(c3)C(=O)OC4=O)ccc21 ; O=c1oc(=O)c2cc3c(=O)oc(=O)c3cc12 ; O=C(O)c1ccc(-c2ccc(C(=O)O)c(C(=O)O)c2)cc1C(=O)O ; O=C(O)c1cc(C(=O)O)c(C(=O)O)cc1C(=O)O ; Nc1ccc(N)cc1 ; Nc1ccc(-c2ccc(-c3ccc(N)cc3)cc2)cc1]

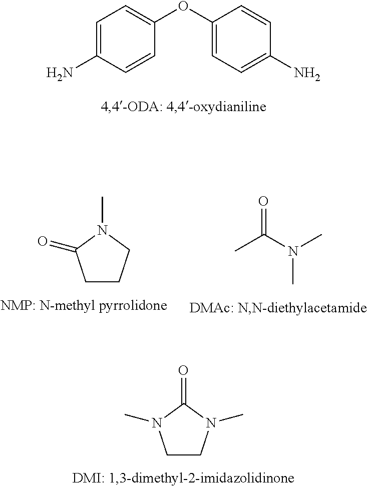

### Synthesis Example of Polyamic Acid (Polyimide Precursor) Solution (Varnish)

### [Synthesis Example 1] (Used in Example 1)

3300 g of NMP and 268.80 g (2.485 mol) of PPD were put into a 5 L separable flask, and after stirring at 50° C., for 30 minutes under a nitrogen atmosphere, 725 g (2.464 mol) of s-BPDA and 1000 g of NMP were added to react.

To the reaction mixture, 7.74 g (0.021 mol) of s-BPTA were added and stirred, and then the reaction was completed. The final viscosity was 3482 Poise at 30° C., the total acid-amine ratio was 1.00, and the monomer concentration was 18.9 wt %. The obtained varnish was diluted with NMP so that the monomer concentration was 10.0 wt %. The viscosity was 50.2 Poise at 30° C.

### [Synthesis Example 2] (Used in Example 2)

4100 g of NMP and 21.50 g of water were charged into a 5 L separable flask and heated to 50° C., under a nitrogen atmosphere. 30.11 g (0.278 mol) of PPD was added and stirred for 1 hour. Thereafter, 97.25 g (0.331 mol) of s-BPDA and 100 g of NMP were added, and stirred continuously for 1 hour.

404.35 g (1.374 mol) of s-BPDA, 158.05 g (1.461 mol) of PPD, and 100 g of NMP were added to the reaction mixture, and stirred continuously for 2 hours. Thereafter, 5.12 g (0.018 mol) of s-BPDA was added and reacted.

Finally, 6.37 g (0.017 mol) of s-BPTA was added and stirred for 2 hours to complete the reaction. The final viscosity was 29.8 Poise at 25° C., the total acid-amine ratio was 1.00, and the monomer concentration was 14.0 wt %.

### [Synthesis Example 3] (Used in Example 3)

3000 g of NMP and 21.50 g of water were charged into a 5 L separable flask, and heated to 50° C., under a nitrogen atmosphere. 52.59 g (0.202 mol) of DATP was then added and stirred for 30 minutes. 77.99 g (0.265 mol) of s-BPDA and 650 g of NMP were added, and stirred continuously for 3 hours.

282.25 g (0.959 mol) of s-BPDA. 276.04 g (1.060 mol) of DATP, and 650 g of NMP were added to the reaction mixture, and the mixture was stirred for 2 hours. Thereafter. 4.08 g (0.14 mol) of s-BPDA was added and reacted.

Finally, 8.78 g (0.024 mol) of s-BPTA was added and stirred for 2 hours to complete the reaction. The final viscosity at this time was 70.7 Poise at 30° C., the total acid-amine ratio was 1.00, and the monomer concentration was 14.0 wt %.

### [Synthesis Example 4] (Used in Example 4)

3200 g of NMP and 406.86 g (2.032 mol) of 4,4′-ODA were charged into a 5 L separable flask, and stirred at 50° C., for 1 hour under a nitrogen atmosphere, and then 425.42 g of PMDA (1.951 mol) and 950 g of NMP were added and reacted.

20.65 g (0.081 mol) of PMA was added to the reaction mixture and stirred for 2 hours to complete the reaction. The final viscosity at this time was 12.2 Poise at 30° C., the total acid-amine ratio was 1.00, and the monomer concentration was 17.1 wt %.

### [Synthesis Example 5] (Used in Example 5)

4100 g of NMP and 21.50 g of water were charged into a 5 L separable flask and heated to 50° C., under a nitrogen atmosphere. 30.11 g (0.278 mol) of PPD was added and stirred for 1 hour. Thereafter, 97.25 g (0.331 mol) of s-BPDA and 100 g of NMP were added, and stirred continuously for 1 hour.

404.35 g (1.374 mol) of s-BPDA, 158.05 g (1.461 mol) of PPD, and 100 g of NMP were added to the reaction mixture, and stirred continuously for 2 hours. Thereafter, 5.12 g (0.018 mol) of s-BPDA was added and reacted.

Finally, 5.15 g (0.035 mol) of phthalic anhydride was added and stirred for 2 hours to complete the reaction. The final viscosity at this time was 29.5 Poise at 25° C., the total acid-amine ratio was 1.00, and the monomer concentration was 13.9 wt %. The total acid-amine ratio at this time was calculated as (number of moles of s-BPDA+number of moles of phthalic anhydride+2)+ (number of moles of PPD).

### [Synthesis Example 6] (Used in Comparative Example 1)

3800 g of NMP and 20.00 g of water were charged into a 5 L separable flask, and heated to 50° C., under a nitrogen atmosphere. Then, 43.01 g (0.398 mol) of PPD was added and stirred for 1 hour. 153.55 g (0.522 mol) of s-BPDA and 100 g of NMP were added, and stirred continuously for 3 hours.

563.02 g (1.914 mol) of s-BPDA, 225.79 g (2.088 mol) of PPD, and 100 g of NMP were added to the reaction mixture, and the mixture was stirred for 2 hours. Thereafter, 5.85 g (0.019 mol) of s-BPDA was added and reacted.

Finally, 10.92 g (0.030 mol) of s-BPTA was added and stirred for 2 hours to complete the reaction. The final viscosity at this time was 51.9 Poise at 30° C., the total acid-amine ratio was 1.00, and the monomer concentration was 20.0 wt %.

### [Synthesis Example 7] (Used in Comparative Example 2)

3900 g of NMP and 188.16 g (1.740 mol) of PPD were charged into a 5 L separable flask and stirred at 50° C., for 30 minutes under a nitrogen atmosphere, and then 501.1 g (1.704 mol) of s-BPDA and 400 g of NMP were added and reacted.

0.64 g (0.002 mol) of s-BPTA was added to the reaction mixture and reacted to complete the polymerization. The final viscosity at this time was 31.8 Poise at 25° C., the total acid-amine ratio was 0.980, and the monomer concentration was 13.8 wt %.

### [Synthesis Example 8] (Used in Comparative Example 3)

3413.80 g of NMP, 161.72 g (1.495 mol) of PPD, and 2.41 g (0.012 mol) of ODA were charged into a 5 L separable flask, and the mixture was stirred at 50° C., for 30 minutes under a nitrogen atmosphere. Thereafter. 439.11 g (1.492 mol) of s-BPDA was added, and while stirring under a nitrogen atmosphere, the solution temperature was raised to about 90° C., over 10 minutes to completely dissolve the starting material. Further, stirring was continued at 90° C., for 3 hours.

The solution after the above reaction was quickly cooled to about 50° C., in a water bath, and then 29.45 g of 1% NMP solution of 3-aminopropyltriethoxysilane (γ-APS) was added to perform alkoxysilane modification, and an acrylic surface conditioner was added in an amount of 0.02 parts by weight to 100 parts by weight of the solid content of the alkoxysilane-modified polyamide acid. To this alkoxysilane-modified polyamide acid solution, 4.552 g (0.031 mol) of phthalic anhydride was added and stirred for 60 minutes under a nitrogen atmosphere at 50° C., to react and complete the polymerization. The final viscosity at this time was 29.4 Poise at 23° C., the total acid-amine ratio was 1.00, and the monomer concentration was 11.1 wt %.

### [Synthesis Example 9] (Used in Comparative Example 4)

3.500 g of N, N-dimethylacetamide and 650.07 g (2.209 mol) of s-BPDA were charged into a SL separable flask, and stirred thoroughly, then 241.88 g (2.236 mol) of PPD and 600 g of N,N-dimethylacetamide were added and stirred at room temperature. After stirring. 1.316 g (0.004 mol) of s-BPDA and 8.192 g (0.022 mol) of s-BPTA were added, and the mixture was stirred at room temperature for about 6 hours to complete the polymerization. The final viscosity at this time was 315 Poise 30° C., the total acid-amine ratio was 1.00, and the monomer concentration was 18.0 wt %

### [Synthesis Example 5] (Used in Example 5)

3700 g of DMI and 147.84 g (1.367 mol) of PPD were charged into a 5 L separable flask, and stirred at 50° C., for 30 minutes under a nitrogen atmosphere, and then 398.14 g (1.353 mol) of s-BPDA and 750 g of DMI were added and reacted.

5.01 g (0.014 mol) of s-BPTA was added to the reaction mixture and stirred to complete the reaction. The final viscosity was 70.6 Poise at 30° C., the total acid-amine ratio was 1.00, and the monomer concentration was 11.0 wt %.

### Examples 1 to 6, Comparative Examples 1 to 4

The polyamic acid solution prepared in the synthesis example was spin-coated onto a non-alkali glass wafer, and heated at 120° C., 150° C., 200° C., and 250° C., for 10 minutes each, and at 450° C., for 5 minutes to form a polyimide film with a thickness of 10 μm, and thus, a polyimide/glass laminate was produced.

Charge-up characteristics was measured using the manufactured polyimide/glass laminate. The results are shown in Table 1.

TABLE 1

| | monomer | | monomer | | tetracarboxylic | | | viscosity | | | |
|---|---|---|---|---|---|---|---|---|---|---|---|
| | compo- | | concentration | monomer ratio (acid | acd or phthalic | | (X + | (measurement | | LR | evalu- |
| | sition | solvent | (wt %) | dianhydride/diamine) | anhydride | X/Y | Z/2)/Y | temperature) | Mw | ratio | ation |
| Example | s-BPDA/ | NMP | 10 | 0.9915 | s-BPTA | 1.00 | — | 50.2 P | 248056 | 0.86 | ∘ |
| 1 | PPD | | | | | | | (30° C.) | | | |
| Example | s-BPDA/ | NMP | 14 | 0.99 | s-BPTA | 1.00 | — | 29.8 P | 124451 | 0.68 | ∘ |
| 2 | PPD | | | | | | | (25° C.) | | | |
| Example | s-BPDA/ | NMP | 14 | 0.981 | s-BPTA | 1.00 | — | 70.7 P | 102236 | 0.74 | ∘ |
| 3 | DATP | | | | | | | (30° C.) | | | |
| Example | PMDA/ | NMP | 17 | 0.96 | PMA | 1.00 | — | 12.2 P | 91624 | 0.70 | ∘ |
| 4 | ODA | | | | | | | (30° C.) | | | |
| Example | s-BPDA/ | NMP | 14 | 0.99 | phthalic | 0.99 | 1.00 | 29.5 P | 125303 | 0.62 | ∘ |
| 5 | PPD | | | | anhydride | | | (25° C.) | | | |
| Example | s-BPDA/ | DMI | 11 | 0.99 | s-BPTA | 1.00 | — | 70.6 P | 225761 | 0.59 | ∘ |
| 6 | PPD | | | | | | | (30° C.) | | | |
| Comp. | s-BPDA/ | NMP | 20 | 0.988 | s-BPTA | 1.00 | — | 51.9 P | 75813 | 0.41 | x |
| Ex. 1 | PPD | | | | | | | (30° C.) | | | |
| Comp. | s-BPDA/ | NMP | 14 | 0.979 | s-BPTA | 0.98 | — | 31.8 P | 130558 | 0.19 | x |
| Ex. 2 | PPD | | | | | | | (25° C.) | | | |
| Comp. | s-BPDA/ | NMP | 11 | 0.99 | phthalic | 0.99 | 1.00 | 29.4 P | 189700 | 0.19 | x |
| Ex. 3 | PPD/ODA | | | | anhydride | | | (23° C.) | | | |
| Comp. | s-BPDA/ | DMAc | 18 | 0.99 | s-BPTA | 1.00 | — | 315 P | 191763 | 0.37 | x |
| Ex. 4 | PPD | | | | | | | (30° C.) | | | |

Comp. Ex. = Comparative Example

### INDUSTRIAL APPLICABILITY

The poly imide of the present invention is suitably used in electronic device applications such as flexible device substrates.

### EXPLANATION OF REFERENCE

1 Polyimide film
2a, 2b Electrode
3 Substrate
4 Dipole
5 Electrons (charge)

1. A polyimide precursor for manufacturing flexible electronic device substrates,
wherein when a polyimide film having a thickness of 10 μm is formed using the polyimide precursor, and a pair of electrodes is formed with a distance d on the polyimide film, and when the polyimide film is irradiated with a laser beam while applying a DC voltage with an electric field strength of 0.1 to 10 V/μm between the pair of electrodes;
two SHG lights are observed between the pair of electrodes and satisfy a symmetry ratio of 0.5 or more,
wherein the symmetry ratio is a value expressed by the following equation:
Symmetry ratio (LR ratio)=Iₛₘₐₗₗ/I_{large}
wherein, I_{large} represents a peak intensity of the SHG light with larger intensity, and Iₛₘₐₗₗ represents a peak intensity of the SHG light with smaller intensity.

2. The polyimide precursor according to claim 1, wherein the polyimide precursor has a weight average molecular weight of 80,000 to 300,000.

3. The polyimide precursor according to claim 2, wherein the polyimide precursor comprises at least polyamic acid.

4. The polyimide precursor according to claim 1, wherein all tetracarboxylic acid components and all diamine components constituting the polyimide precursor satisfy the following equation:
$$1 \leq X / Y \leq 1.05$$
wherein X represents a number of moles of the tetracarboxylic acid component, and Y represents a number of moles of the diamine component.

5. The polyimide precursor according to claim 1, wherein the polyimide precursor is composed of a tetracarboxylic acid component, a diamine component, and a carboxylic acid monoanhydride, and satisfies the following equations (1) and (2):
$$0.97 \leq X / Y < 1. \qquad Equation ( 1 )$$
$$1. \leq ( X + Z / 2 ) / Y \leq 1.05 \qquad Equation ( 2 )$$
wherein X represents a number of moles of the tetracarboxylic acid component, Y represents a number of moles of the diamine component, and Z represents a number of moles of the carboxylic acid monoanhydride.

6. The polyimide precursor according to claim 4, wherein the proportion of 3,3′,4,4′-biphenyltetracarboxylic dianhydride in all tetracarboxylic acid components is 60 mol % or more, and the amount of p-phenylenediamine in all diamine components is 60 mol % or more.

7. A polyimide film for a flexible electronic device substrate obtained from the polyimide precursor according to claim 1.

8. A laminate comprising the polyimide film according to claim 7 and a glass substrate.

9. A flexible electronic device substrate comprising the polyimide film according to claim 7.

10. A flexible electronic device comprising the flexible electronic device substrate according to claim 9 and a TFT element.

11. A method for manufacturing a flexible electronic device according to claim 9, comprising applying a solution comprising a polyimide precursor onto a carrier substrate, and imidizing the solution to form a laminate comprising the carrier substrate and a polyimide film.

12. The polyimide precursor according to claim 5, wherein a proportion of 3,3′,4,4′-biphenyltetracarboxylic dianhydride in all tetracarboxylic acid components is 60 mol % or more, and an amount of p-phenylenediamine in all diamine components is 60 mol % or more.
